(19) United States
(12) Patent Application Publication
(10) Pub. No.: US 2004/0043536 A1
(43) Pub. Date: Mar. 4, 2004

(54) Method of producing integrated circuit package units

(75) Inventors: Dick Hong, Taichung City (TW); Dean Pan, Kaohsiung City (TW); Ching-Yi Tsai, Taichung City (TW)

Correspondence Address: OSTROLENK FABER GERB & SOFFEN, 1180 AVENUE OF THE AMERICAS, NEW YORK, NY, 100368403

(73) Assignee: Uni-Tek System, Inc.

(21) Appl. No.: 10/646,154

(22) Filed: Aug. 22, 2003

(30) Foreign Application Priority Data
Aug. 27, 2002 (TW) 091119456

(51) Int. Cl. H01L 21/60

(52) U.S. Cl. 438/112; 438/123; 438/124; 438/111

(57) ABSTRACT

A method of producing individual integrated circuit package units includes the steps of: providing a base which includes a leadframe, a plurality of package precursors, and a continuous encapsulating epoxy layer bonded integrally with the leadframe; and singulating the package precursors. The leadframe has a plurality of metallic connection bars and extension parts formed integrally with the connection bars. The package precursors are singulated by cutting the leadframe and the epoxy layer along first and second cutting streets. The cutting of the base is performed by cutting into the first and second cutting streets with a cutting tool, which can be a single-blade or dual-blade, thereby separating the connection bars from the inner leads.

### BACKGROUND OF THE INVENTION

1. Field of the Invention

The invention relates to a method of producing integrated circuit package units, more particularly to a method in which a plurality of integrated circuit package units are produced through a singulation process from a preformed substrate.

2. Description of the Related Art

Referring to FIGS. 1, 2 and 3, a conventional matrix type substrate 1 for producing integrated circuit package units includes a grid-like array of preformed QFN (Quad Flat Non-Leaded) package precursors 11 formed on a leadframe 12, and a plurality of intersecting singulation streets 13 extending along the borderlines of the package precursors 11. The center-to-center distance between two adjacent package precursors 11 is represented by (L1). Each package precursor 11 includes a semiconductor chip 111, and inner leads 122 electrically connected to the semiconductor chip 111. The dimension of each inner lead 122 is denoted by (Wo) A continuous encapsulating epoxy layer 112 encloses the semiconductor chips 111 of the package precursors 11, and is bonded integrally to the leadframe 12. The leadframe 12 includes a plurality of intersecting connection bars 121 which extend along the borderlines of the package precursors 11 and which are formed integrally with the inner leads 122 of the package precursors 11. FIG. 2 is provided with dotted lines at the left side thereof to show one part of the substrate 1 which has not been cut, and with solid lines at the right side thereof to show another part of the substrate 1 which has been cut. The singulation streets 13 cover the metal layer of the leadframe 12 (i.e., the connection bars 121) and parts of the encapsulating epoxy layer 112 underlying the connection bars 121. A cutting device, which has a cutting blade 2 made of a material containing diamond, is used to cut off the connection bars 121 and the underlying epoxy layer 112 so as to separate structurally and electrically the package precursors 11 to form individual integrated circuit package units, one of which is shown in FIG. 3. The inner leads 122 are left in each package unit after singulation. However, since the connection bars 121 are made of copper or similar material, which is soft and ductile, the cutting blade 2 must operate in a slow and toilsome manner like spooning up ice cream with a scoop. Furthermore, the metal chips produced upon cutting can stick to the cutting blade 2, loaded the blade, and deteriorate the blade cutting ability. Although the conventional cutting device provides a water jet to spray on the cutting point, since the cutting is performed continuously along the singulation streets 13, it is difficult to self-sharpen the blade grit or remove the metal chips from the cutting blade 2. This phenomenon tends to attenuate the sharpness of the cutting blade 2, increases the rate of wear of the cutting blade 2, and decreases the rate of cutting. Generally, the cutting rate of the cutting blade 2 is as slow as 1-5 mm/sec. Moreover, in order to match the width of the connecting bars 121, it is necessary to properly select a suitable width for the cutting blade 2. In addition, there is an incidence of burring at the edge of the inner leads 122 after singulation, as shown in FIG. 4, which can result in short-circuiting in the semiconductor chip 111 especially when the burr size is large enough.

Although the prior art has suggested a process of manufacturing integrated circuit package units, which utilizes a half etching technology to reduce the thickness of a metal layer of a leadframe, this manufacturing process still cannot solve the aforesaid problems encountered in the conventional singulation process.

### SUMMARY OF THE INVENTION

Therefore, the object of the present invention is to provide a method of producing integrated circuit package units that is capable of overcoming the aforementioned drawbacks of the prior art.

According to this invention, a method of producing individual integrated circuit package units comprises the steps of: providing a base which includes a leadframe and a plurality of package precursors formed on the leadframe; and singulating the package precursors. Each of the package precursors has inner leads, and a semiconductor chip connected electrically to the inner leads. The leadframe has a plurality of metallic connection bars extending along borderlines of the package precursors, and extension parts branching from two sides of the connection bars. The extension parts are formed integrally with the connection bars, and are connected respectively and directly to the inner leads of the package precursors. The base further has a continuous encapsulating epoxy layer that encloses the semiconductor chips of the package precursors and that are bonded integrally with the leadframe. The package precursors are singulated by cutting the leadframe and the encapsulating epoxy layer along first and second cutting streets which extend respectively along and at two opposite sides of the connection bars and which extend through the extension parts. The cutting of the base is performed by cutting into the first and second cutting streets with a cutting tool, thereby separating the connection bars from the inner leads.

### BRIEF DESCRIPTION OF THE DRAWINGS

Other features and advantages of the present invention will become apparent in the following detailed description of the preferred embodiment with reference to the accompanying drawings, of which:

FIG. 1 is a fragmentary schematic view of a conventional matrix type substrate;

FIG. 2 is a fragmentary sectional view of the conventional substrate of FIG. 1;

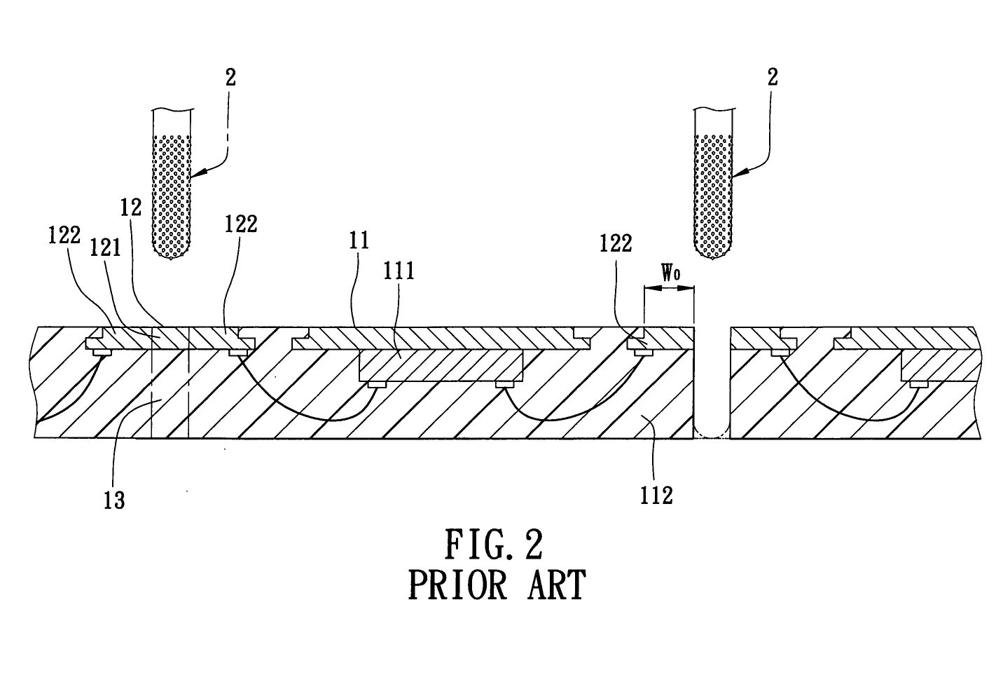

FIG. 3 illustrates a single package unit after singulation of the conventional substrate;

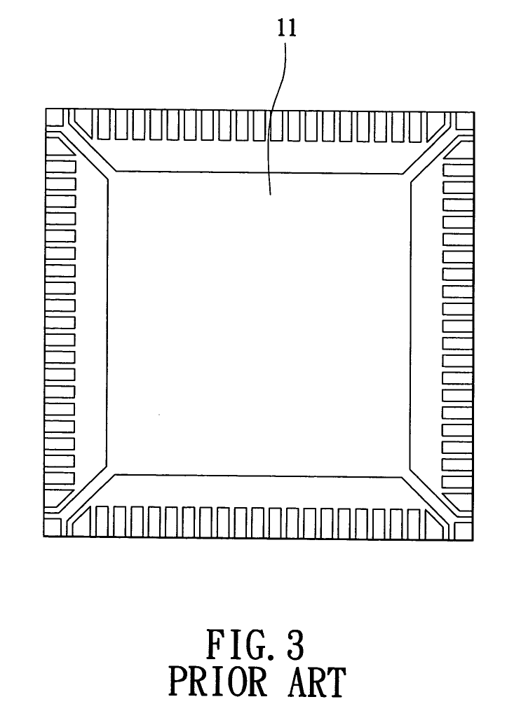

FIG. 4 illustrates burrs occurring at the edge of inner leads of the conventional substrate after singulation;

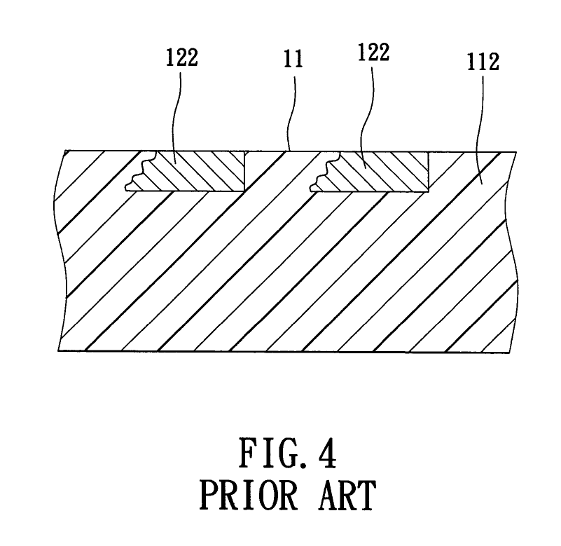

FIG. 5 is a fragmentary schematic view of a matrix base used in a preferred embodiment of a method of producing integrated circuit package units according to the present invention;

FIG. 6 is an enlarged schematic view of an encircled portion of FIG. 5;

FIG. 7 is a fragmentary sectional view of the matrix base of FIG. 5;

FIG. 8 is a fragmentary sectional view of a singulated integrated circuit package unit with the inner leads thereof being sectioned; and

FIG. 9 is a fragmentary schematic view showing the extension parts of a leadframe of the matrix base to be cut by a cutting tool.

### DETAILED DESCRIPTION OF THE PREFERRED EMBODIMENT

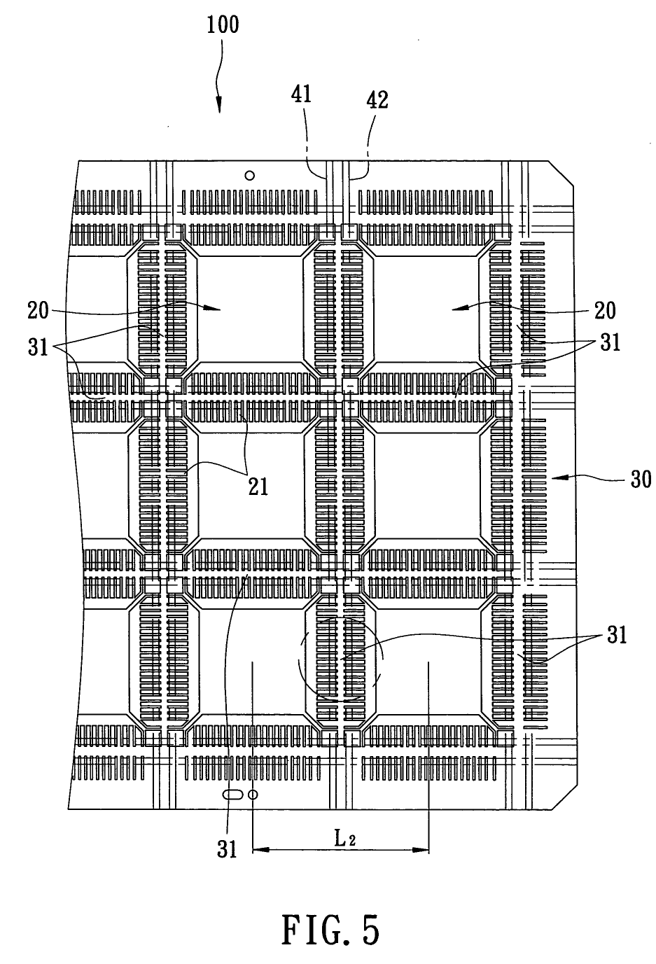

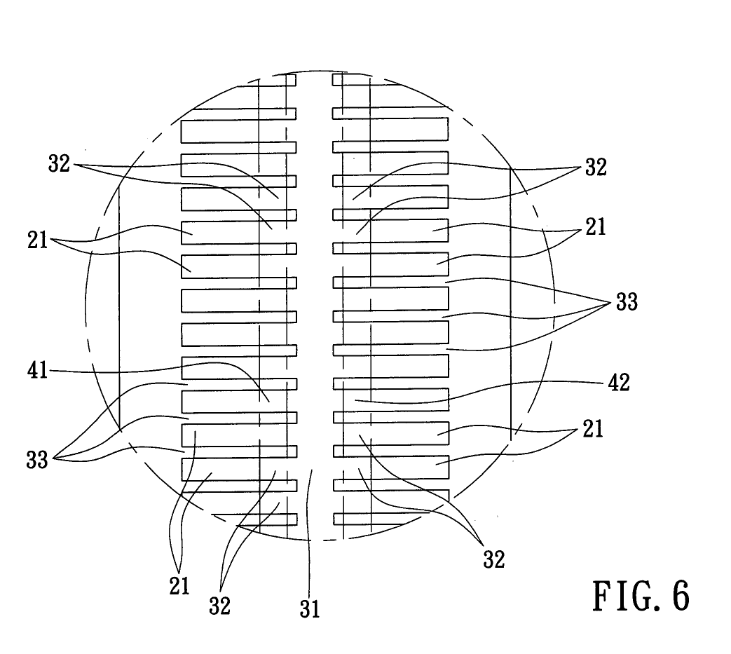

Referring to FIGS. 5 to 7, a method of producing individual integrated circuit package units embodying the preferred embodiment of the present invention comprises first and second steps.

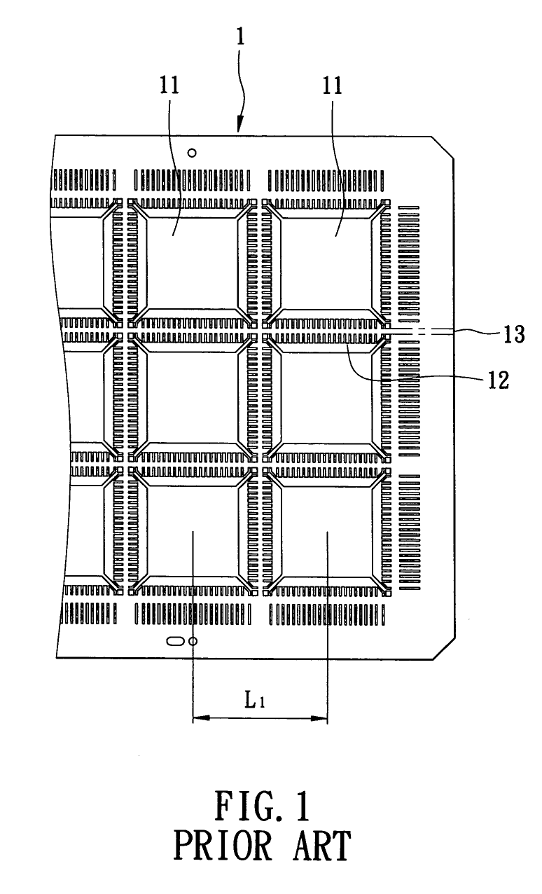

The first step is to provide a matrix base 100, which includes a plurality of preformed integrated circuit package precursors. In this embodiment, the matrix base 100 includes a leadframe 30, and is preformed with a grid-like array of QFN package precursors 20 formed on the leadframe 30. Each of the package precursors 20 has inner leads 21, and a semiconductor chip 22 connected electrically to the inner leads 21. The center-to-center distance (L2) between two adjacent ones of the package precursors 20 is greater than the center-to-center distance (L1) between two adjacent ones of the package precursors 11 of the conventional substrate 1 shown in FIG. 1. The leadframe 30 is made of copper or a similar material, and has a plurality of intersecting metallic connection bars 31 extending along borderlines of the package precursors 20, and extension parts 32 branching from two sides of the connection bars 31. The extension parts 32 are formed integrally with the connection bars 31, and are connected respectively and directly to the inner leads 21 of the package precursors 20. The extension parts 32 extend towards the inner leads 21 from two opposite sides of the connection bars 31. The extension parts 32 are spaced apart so that gaps 33 are formed therebetween. Furthermore, the length of the inner leads 21 of the package precursors 20 is equal to that of the inner leads 122 of the conventional package precursors 11, which is a standard length of a QFN package unit. The matrix base 100 further has a continuous encapsulating epoxy layer 23 that encloses the semiconductor chips 22 of the package precursors 20 and that are bonded integrally with the leadframe 30. The encapsulating epoxy layer 23 is made of an epoxy resin, and the epoxy resin fills the gaps 33 between the extension parts 32.

In the second step, the package precursors 20 are singulated by cutting the leadframe 30 and the encapsulating epoxy layer 23 along first and second cutting streets 41, 42 which extend respectively along and at two opposite sides of the connection bars 31 and which extend through the extension parts 32.

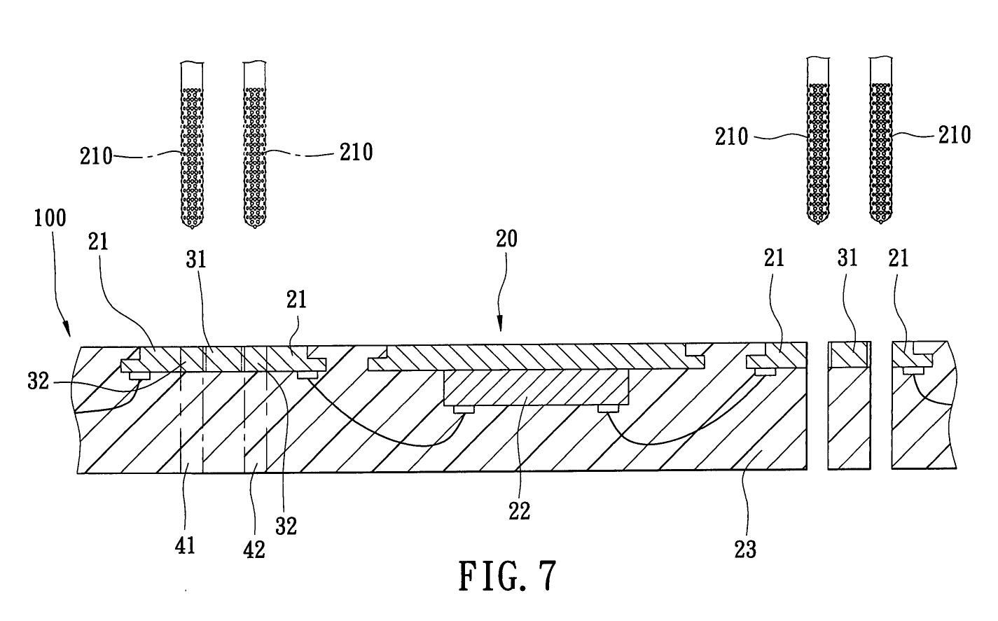

The cutting of the matrix base 100 is performed by using two rotary cutting tools 210 and by cutting respectively into the first and second cutting streets 41, 42 so as to cut away the extension parts 32 and so as to separate the connection bars 31 from the inner leads 21, as illustrated by the solid lines at the right side of FIG. 7, thereby obtaining a plurality of singulated package precursors 20 (not shown).

It should be noted that the cutting of the leadframe 30 along the first and second cutting streets 41, 42 can be performed simultaneously by a dual-blade cutting tool 210 or can be performed by using a single-blade cutting tool (not shown) that cuts through the first and second cutting streets 41, 42 consecutively.

Therefore, the present invention provides the following advantages:

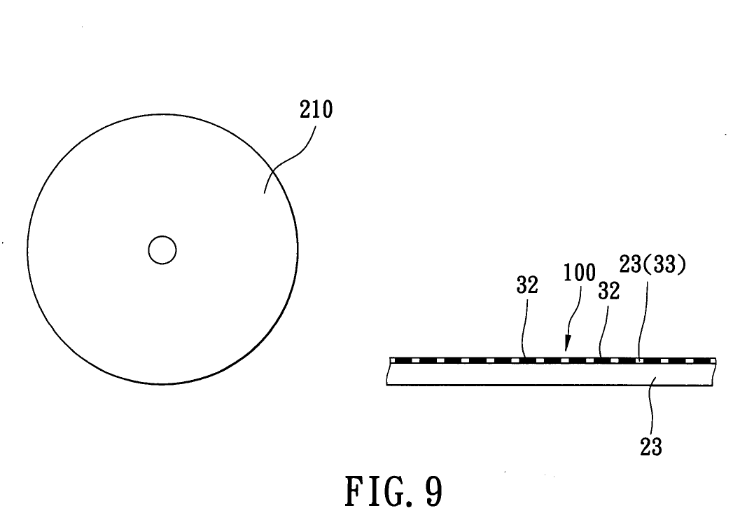

1. In the present invention, the first and second cutting streets 41, 42 are kept away from the connection bars 31, and are arranged to fall within the extension parts 32 which are easier to be cut by the cutting tools 210 as compared to the connection bars 31. Since the gaps 33 between the extension parts 32 are filled by the encapsulating epoxy layer 23, as shown in FIG. 9, the metal of the leadframe 30 along the first and second cutting streets 41, 42 is discontinuous and is interrupted by the epoxy layer 23. During the cutting operation, the cutting tools 210 simultaneously cut into the metal of the leadframe 30 and the epoxy layer 23. Since the cutting tools 210 cut into the extension parts 32 intermittently, rather than cut into the connection bars 31 continuously, and since the cutting tools 210 reach and cut the hard epoxy layer 23 before the cut metal chips (not shown) of the extension parts 32 are able to stick to the cutting tools 210, the cut metal chips are pushed away from the cutting tools 210 by the chips or particles of the epoxy layer 23 resulting from the cutting of the epoxy layer 23. Thus, the cut metal chips can be easily washed away by a water jet from the first and second cutting streets 41, 42. As a result, the sharpness of the cutting tools 210 can be maintained in a good condition, and the wear of the cutting tools 210 can be lessened. Although the number of the cutting streets used in the present invention is twice of that used in the conventional process, experiments show that the cutting speed in the present invention can be 80 mm/sec, which is much faster than that of the cutting operation performed in the conventional process for manufacturing QFN package units so that the production rate is relatively increased in the present invention.

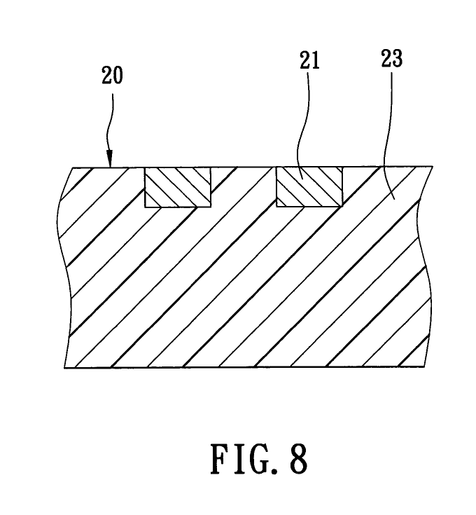

2. The quality of the package units produced by the present invention is good since the blade sharpness is maintained in a good condition. As a result, the incidence of burring at the inner leads 21 of the package units is reduced, as illustrated in FIG. 8.

3. Since the connection bars 31 are not cut directly by the cutting tools 210, the width of the cutting tools 210 is not limited by the connection bars 3l. Therefore, as compared with the conventional cutting blade 2, the cutting tools 210 used in the present invention can be thinner and can thus have a reduced contact area with the metal. Furthermore, the present invention eliminates the incomplete cutting problem occurring often in the conventional process.

4. The matrix base 100 used in the present invention can be produced by the same process as that used in the conventional process except that the center-to-center distance of the package precursors 20 is enlarged and that the leadframe 30 is provided with the extension parts 32 and the inner leads 21.

Although the preferred embodiment of the present invention is directed to the production of QFN package units, the present invention is not limited thereto. The present invention is applicable to the production of any integrated circuit package unit other than QFN package units.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

We claim:

1. A method of producing individual integrated circuit package units, comprising:
providing a base which includes a leadframe and a plurality of package precursors formed on said leadframe, each of said package precursors having inner leads and a semiconductor chip connected electrically to said inner leads, said leadframe having a plurality of metallic connection bars extending along borderlines of said package precursors, and extension parts branching from two sides of said connection bars, said extension parts being formed integrally with said connection bars and being connected respectively and directly to said inner leads of said package precursors, said extension parts being spaced apart from each other, said base further having a continuous encapsulating epoxy layer that encloses said semiconductor chips of said package precursors and that are bonded integrally with said leadframe; and
singulating said package precursors by cutting said leadframe and said encapsulating epoxy layer along first and second cutting streets which extend respectively along and at two opposite sides of said connection bars and which extend through said extension parts, wherein the cutting of said base is performed by cutting into said first and second cutting streets with a cutting tool, thereby separating said connection bars from said inner leads.

2. The method as claimed in claim 1, wherein said package precursors are arranged in a grid-like array, said connection bars intersecting each other.

3. The method as claimed in claim 1, wherein said cutting tool is a single-blade cutting tool.

4. The method as claimed in claim 1, wherein said cutting tool is a dual-blade cutting tool.
